(19) United States
(12) Patent Application Publication
(10) Pub. No.: US 2026/0169058 A1
(43) Pub. Date: Jun. 18, 2026

(54) DYNAMIC TEST MANAGEMENT BURN-IN DEVICE AND SYSTEM

(71) Applicant: King Yuan ELECTRONICS CO., LTD., Hsinchu City (TW)

(72) Inventors: Shih-Bou Chang, Hsinchu City (TW); Ta-Kang Liu, Hsinchu City (TW); Ming-Hsien Lee, Hsinchu City (TW); Yung-Jen Tang, Hsinchu City (TW); Tsung-Yi Lin, Hsinchu City (TW)

(73) Assignee: King Yuan ELECTRONICS CO., LTD., Hsinchu City (TW)

(21) Appl. No.: 19/253,077

(22) Filed: Jun. 27, 2025

(30) Foreign Application Priority Data
Dec. 12, 2024 (TW) 113148488

(51) Int. Cl. G01R 31/28; G01R 1/04

(52) U.S. Cl. CPC G01R 31/2874; G01R 1/0458; G01R 31/2863

(57) ABSTRACT

A dynamic test management burn-in device and system are provided. In certain embodiments, the device includes multiple test sockets, multiple power converters, and multiple controllers. Each power converter receives a first power from a power source and supplies a second power to the respective test sockets. Each controller includes a power detection unit that monitors the second power and adjusts the output or activation of the power converters based on the detection results from the power detection units. A voltage of the first power is higher than that of the second power, while a current of the first power is lower than that of the second power.

### CROSS-REFERENCE TO RELATED APPLICATION

This non-provisional application claims priority under 35 U.S.C. § 119(a) to Patent Application No. 113148488 filed in Taiwan, R.O.C. on Dec. 12, 2024, the entire contents of which are hereby incorporated by reference.

### BACKGROUND

### Technical Field

The present disclosure provides a dynamic test management burn-in device and system, and particularly relates to a burn-in device and a burn-in system capable of automatically regulating a test power supply and a burn-in temperature in a chip burn-in test process.

### Related Art

With the rapid development of artificial intelligence (AI) technology and other advanced computing cluster processing technologies, the computational power and power consumption of chips have increased dramatically, bringing significant challenges and opportunities to the semiconductor packaging and testing industry.

Specifically, for burn-in test, conventional hardware systems can no longer meet the demands of high-power devices under test (DUTs). On one hand, the circuit design of conventional test boards struggles to support or provide high-wattage power. For example, in the case of chip testing with a current maximum thermal design power (TDP) of 700 W, the test board must continuously supply over 58 amperes of current to each DUT. Moreover, when the testing system is required to deliver high currents to support high-power DUTs, especially when a single test board is used to simultaneously test multiple high-power DUTs, the system must be equipped with thicker wires or circuits. This leads to a bulky testing system with complex wiring.

On the other hand, during the entire burn-in testing process, the current requirements for testing high-power chips are not constant. For instance, the initial current required for starting the test is greater than that during the steady-state testing phase. Additionally, in the event of an overload, the system must reduce the testing current instantly. However, existing burn-in systems cannot dynamically and adaptively adjust the power supply states during testing. Furthermore, since high-power chips generate significant heat during operation, thermal control requirements pose unprecedented challenges to the chip testing industry.

### SUMMARY

In view of above, the present disclosure provides a dynamic test management burn-in device and system, which can completely solve the above problems.

To achieve above objective, the present disclosure provides a dynamic test management burn-in device, which includes a plurality of test sockets, a plurality of power converters, and a plurality of controllers. Each test socket is configured to load a device under test. The power converters are electrically coupled with the test sockets, and each power converter is configured to receive a first power from a power source and to provide a second power to the respective test sockets. The controllers are electrically coupled with the power converters; and the controllers include a plurality of power detection units configured to detect the second power. The controllers control output or activation of the power converters based on a detection result from the power detection units to supply the second power to the respective test sockets; and a voltage of the first power is higher than that of the second power, while a current of the first power is lower than that of the second power.

To achieve above objective, the present disclosure provides a dynamic test management burn-in device, which includes a power source, a plurality of test sockets, a plurality of power converters, and a plurality of controllers. The power source is configured to provide a first power. Each test socket is configured to load a device under test. The power converters are electrically coupled with the power source and the test sockets; each power converter is configured to receive the first power and to provide a second power to the respective test sockets; and the power converters are configured to reduce the voltage of the first power and increase the current of the first power to generate the second power. The controllers are electrically coupled with the power converters; and the controllers include multiple power detection units configured to detect the second power. The controllers control output or activation of the power converters based to a detection result from the power detection units to provide the second power to the respective test sockets.

In summary, according to certain embodiments, the dynamic test management burn-in device and system are equipped with a power monitoring mechanism and a power protection mechanism. In other embodiments, a burn-in temperature control mechanism can also be included. As a result, the burn-in power and temperature can be adaptively adjusted to ensure the stability of the burn-in testing process, thereby improving the reliability and service life of the entire burn-in testing system.

### BRIEF DESCRIPTION OF THE DRAWINGS

FIG. 1A is a system architecture diagram of Embodiment 1 of a dynamic test management burn-in system according to the present disclosure.

FIG. 1B is a system architecture diagram of Embodiment 2 of a dynamic test management burn-in system according to the present disclosure.

FIG. 1C is a system architecture diagram of Embodiment 3 of a dynamic test management burn-in system according to the present disclosure.

FIG. 2 is a system architecture diagram of Embodiment 4 of a dynamic test management burn-in system according to the present disclosure.

FIG. 3 is a system architecture diagram of Embodiment 5 of a dynamic test management burn-in system according to the present disclosure.

FIG. 4 is a system architecture diagram of Embodiment 6 of a dynamic test management burn-in system according to the present disclosure.

FIG. 5 is a system architecture diagram of Embodiment 7 of a dynamic test management burn-in system according to the present disclosure.

FIG. 6 is a system architecture diagram of Embodiment 8 of a dynamic test management burn-in system according to the present disclosure.

### DETAILED DESCRIPTION

Various embodiments are presented below for detailed description, and the embodiments are only used as examples and do not limit the scope of the present disclosure. In addition, some elements are omitted in the drawings in the embodiments to clearly show the technical features of the present disclosure. Furthermore, the same reference numerals will be used for representing the same or similar elements in all drawings, and the drawings of the present disclosure are only for schematic illustration, which may not be drawn to scale, and all details may not be fully presented in the drawings.

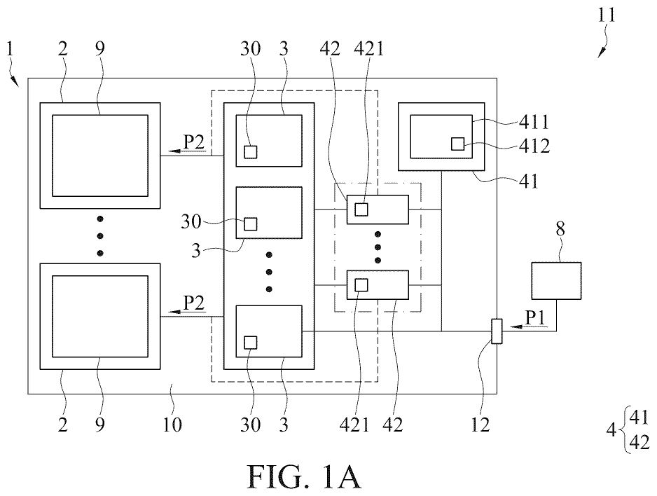

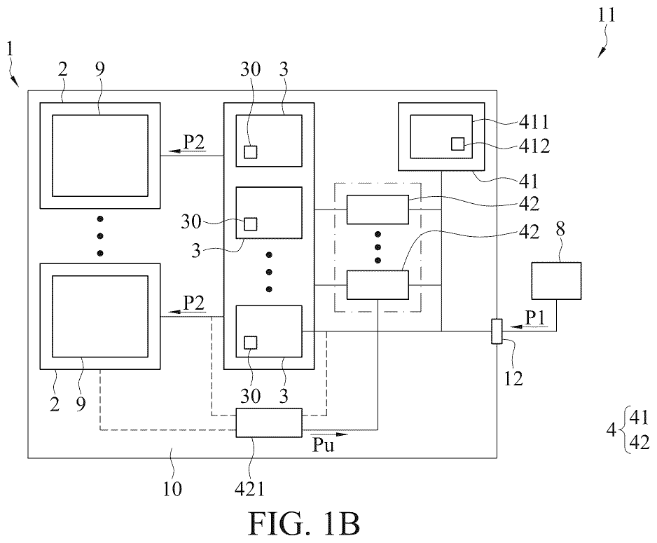

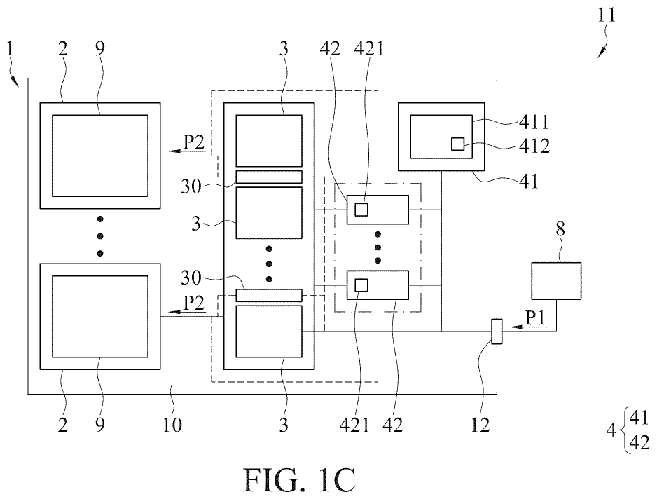

With reference to FIG. 1A, FIG. 1A is a system architecture diagram of Embodiment 1 of a dynamic test management burn-in system 11 according to the present disclosure. In the embodiment shown in FIG. 1A, the dynamic test management burn-in device 1 mainly includes a circuit board 10, a plurality of test sockets 2, a plurality of power converters 3, and a plurality of controllers 4. The test sockets 2, the power converters 3, and the controllers 4 are arranged on the circuit board 10. In some embodiments, the circuit board 10 is a burn-in board.

The test sockets 2 are interconnected in parallel, and each test socket is configured to load a device under test (DUT) 9. The power converters 3 are electrically coupled with the test sockets 2. Each power converter 3 is configured to receive a first power P1 from a power source 8 and supply a second power P2 to the respective test sockets 2 individually. The controllers 4 are electrically coupled with the power converters 3. The controllers 4 include a plurality of power detection units 421 configured to detect the second power P2. The controllers 4 control output or activation (on/off states) of the power converters 3 based on detection results from the power detection units 421, so as to provide the second power P2 to the test sockets 2. Moreover, the voltage of the first power P1 is higher than that of the second power P2, while the current of the first power P1 is lower than that of the second power P2.

Furthermore, the test sockets 2 are specialized connectors for connecting the device under test 9 to a test system in a test stage, allowing comprehensive testing without permanently mounting the device under test 9 onto a test circuit board. In some embodiments, the power converters 3 are DC power converter and are configured to regulate the voltage and current of direct current, such as a booster (for increasing voltage) or a buck converter (for decreasing voltage). In certain embodiments, the power converter 3 is also referred to as a point of load (POL), typically positioned near the test sockets 2 to shorten the transmission path of the second power P2. Moreover, the transmission of high current generally leads to greater losses as the transmission path increases in length. However, in this embodiment, since the power converters 3 are positioned around the test socket 2 respectively, the transmission paths of the second power P2 on the circuit board 10 are shorter than that of the first power P1, thereby significantly reducing transmission losses.

In the embodiment shown in FIG. 1A, the power converters 3 are configured to convert the first power P1 having high voltage and low current into the second power P2 having low voltage and high current. In certain specific embodiments, the voltage of the first power P1 may be 12 V, and the current of that may be 2 A. The voltage of the second power P2 may be 1 V, and the current of that may be 20 A. In other higher-power devices under test (DUTs) 9, to meet the current demand of the test power (second power P2), the current may exceed 50 A, and the voltage of the first power P1 may reach 48V or higher.

In addition, in some embodiments, the quantity of the power converters 3 may be equal to or larger than that of the test sockets 2. In an embodiment in which the quantity of the power converters 3 is larger than that of the test sockets 2, the extra power converters 3 can be configured as backups. For example, if one of the power converters 3 fails, a backup unit can immediately replace it and supply the required testing power. Furthermore, in other embodiments, the power converters 3 can be connected in parallel, allowing the combined current to provide a higher output current, which is more suitable for supplying the test current required by high-power Devices Under Test (DUTs) 9.

In the embodiment shown in FIG. 1A, the controllers 4 include a master controller 41 and multiple slave controllers 42. The master controller 41 is electrically connected to the slave controllers 42, and the slave controllers 42 are electrically connected to the power converters 3 and the test sockets 2. In certain specific embodiments, each test socket 2 corresponds to one slave controller 42, and the slave controller 42 is configured to control the output or activation of at least one power converter 3. In addition, each slave controller 42 may include a power detection unit 421 which can be built into the slave controller 42, as shown in FIG. 1A. In other embodiments, the power detection units 421 may also be independent components electrically connected among the power converters 3, the slave controllers 42, and the test sockets 2, as shown in FIG. 1B.

Furthermore, as shown in FIG. 1A, in an embodiment in which the power detection units 421 are built into the slave controllers 42, the power detection units 421 can be configured to detect the power supplied to the power converters 3, the power outputted by the power converters 3 and the power supplied to the test sockets 2. In other words, in these embodiments, the power detection units 421 can be configured to detect the first power P1 and the second power P2, including the voltage and current of the power supplied to the power converter 3, the voltage and current output by the power converter 3, and the voltage and current supplied to the test socket 2.

With reference to FIG. 1B, which illustrates the system architecture diagram of Embodiment 2 of a dynamic test management burn-in system 11 according to the present disclosure. In an embodiment where the power detection units 421 are independent components, the power detection units 421 can be connected across the input end and output end of the power converters 3. In addition, in certain specific embodiments, the power detection units 421 can also be electrically connected to the test sockets 2. Therefore, the independently configured power detection units 421 can also be configured to detect the first power P1 and the second power P2, including detecting voltages and currents supplied to the power converters 3, the voltages and currents outputted by the power converters 3, and the voltages and currents supplied to the test sockets 2.

Moreover, in an embodiment where the power detection units 421 are electrically connected to the test sockets 2 respectively, the power detection units 421 can also be configured to detect the actual power supplied to the device under test 9 through the test sockets 2 and to transmit feedback power signals Pu to the slave controllers 42. The slave controllers 42 can control each power converter 3 to regulate the outputted second power P2 based on the detected power. In other words, to enhance the stability of the entire system, in some embodiments, the power actually inputted to the device under test 9 can be detected through the power detection units 421. When the detected power indicates an overload or insufficient power supply, the slave controllers 42 can dynamically regulate and control the output of the power converters 3, namely the second power P2.

In one embodiment, the master controller 41 can be a control computer which includes a general processor and is connected to a set of standard input/output systems. Alternatively, the master controller 41 can be implemented using specific logic circuits. In other embodiments, the master controller 41 can be a combination of the specific logic circuit, a general-purpose hardware, software, and a firmware, typically used for controlling the test system. In some embodiments, the master controller 41 can also be connected to a remote computer system to receive a test program from the system and to transmit the test result to the system for analysis. In addition, the slave controllers 42 can be, but are not limited to, a system on a chip (SOC), a field programmable gate array (FPGA) chip or a high performance computing (HPC) chip.

The operation modes in some embodiments are described as follows. When the system is in normal operation, and after the first power P1 of the power source 8 is converted by the power converters 3, the voltage of the first power P1 is reduced, and the current of the first power P1 is increased to generate the second power P2. The second power P2 is then supplied to the test socket 2 and includes the rated voltage and rated current required for the operation of the device under test 9.

However, when an abnormal condition occurs in the system, such as, but not limited to, the following situations: a failure in the power supply device 8, the device under test 9 operating at a higher or lower power level than normal, excessive load current drawn at the start of testing, or other unexpected events causing an overload or insufficient current in the second power P2, the slave controllers 42 can dynamically control the power converters 3 based on the detection results from the power detection units 421. For example, if an overload or insufficient load current is detected, the slave controller 42 can adjust the output by increasing or decreasing the current supply to ensure the stability of the second power P2.

In other embodiments, where the output of the power converters 3 is fixed, the slave controller 42 can dynamically control the activation or deactivation of the power converters 3 based on the detection results from the power detection unit 421 when an abnormal condition occurs in the system, such as an overload or insufficient load current. For example, if the load current is insufficient, the slave controller 42 may activate idle power converters 3; conversely, if the load current is overloaded, it may deactivate excess power converters 3 to ensure the stability of the second power P2 supplied to the device under test 9.

Further elaborating, in this embodiment, the master controller 41 includes a storage unit 411, which stores power converter configuration data 412. The power converter configuration data 412 includes the power converter 3 corresponding to each test socket 2, where each power converter 3 may be one or more units. For example, each power converter 3 is assigned an identification number, and the power converter configuration data 412 records the identification number of the power converter 3 corresponding to each test socket 2. Notably, in other embodiments, the storage unit 411 may also be provided in the slave controller 42, meaning that each slave controller 42 has a storage unit 411. Alternatively, the storage unit 411 may be provided in either the master controller 41 or the slave controller 42, or in both. In other words, the control information for the power converters 3 (i.e., the power converter configuration data 412) may be stored in at least one of the master controller 41 and the slave controller 42.

When the system is in the abnormal condition, the master controller 41 can autonomously update the power converter configuration data 412 based on the detection results from the multiple power detection units 421. For example, if a test socket 2 experiences insufficient current, the master controller 41 can allocate an idle power converter 3 to supply power to the test socket 2. Specifically, this is achieved by adding the identification number of the idle power converter 3 to the list of power converters 3 associated with the test socket 2 in the power converter configuration data 412. Similarly, if a test socket 2 experiences an overload in current, the master controller 41 can deactivate one of the multiple power converters 3 which supply power to the test socket 2. This is done by removing the identification number of the excess power converter 3 from the list of power converters 3 associated with that test socket 2 in the power converter configuration data 412.

In other words, in this embodiment, the master controller 41 can be configured to group the power converter 3 corresponding to each test socket 2 and dynamically adjust the number of power converters 3 in each group based on actual test power demands. Furthermore, in the event of a power converter 3 failure, the master controller 41 can update the power converter configuration data 412 and assign one or more idle power converters 3 to the affected test socket 2.

Specifically, in some embodiments, the dynamic test management burn-in device 1 can implement autonomous dynamic power management, allowing it to independently regulate the output of each power converter 3 or adjust the number of power converters 3 assigned to each test socket 2 based on actual test current conditions. This ensures the stability of the power supplied to the device under test 9. Furthermore, if the dynamic power management mechanism is engaged but abnormal conditions persist, the master controller 41 will proactively intervene, terminate the burn-in test, and immediately shut down the power supply unit 8 to prevent damage to the device under test 9 or the test system.

Moreover, in the embodiment shown in FIG. 1A, each power converter 3 can further include a power feedback unit 30 which is provided in the power converter 3. The power feedback unit 30 can be configured to detect the power (first power P1) inputted to the power converter 3 and the power (second power P2) outputted by the power converter 3. In other words, in these embodiments, the power feedback unit 30 can detect the voltage and current of the power input to the power converter 3, as well as the voltage and current of the power output from the power converter 3. This information allows the slave controllers 42 to determine whether the power converter 3 is operating normally.

On the other hand, with reference to FIG. 1C, FIG. 1C is a system architecture diagram of Embodiment 3 of a dynamic test management burn-in system 11 according to the present disclosure. In other embodiments, the power feedback units 30 are implemented as independent components which are connected across the input terminals and the output terminals of the power converters 3. By adopting this configuration, the independently configured power feedback units 30 can also be configured to detect the voltage and current of the power inputted to the power converters 3 and to detect the voltage and current of the power outputted by the power converters 3. converter 3, as well as the voltage and current of the power output from the power converter 3.

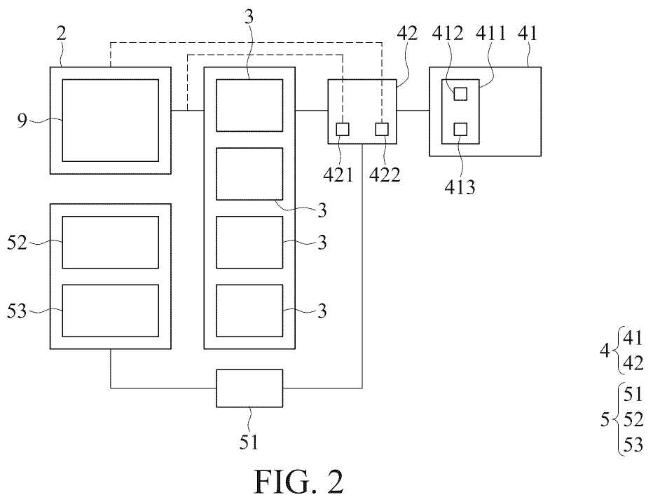

With reference to FIG. 2, it is a system architecture diagram of Embodiment 4 of a dynamic test management burn-in system 11 according to the present disclosure. The burn-in temperature dynamic control method is described below based on Embodiment 4. It is to be noted that the burn-in temperature dynamic control method in Embodiment 4 can be integrated with the dynamic power management method in Embodiment 1, i.e., sharing main components such as the master controller 41, the and slave controllers 42. Additionally, although only one temperature control module 5 is shown in FIG. 2, in most embodiments, each test socket 2 should correspond to one temperature control module 5.

In the embodiment shown in FIG. 2, each slave controller 42 includes a temperature sensing unit 422 configured to detect the temperature of the device under test 9 in each test socket 2. The master controller 41 or slave controllers 42 can use this sensing result to control the temperature control module 5 via the slave controllers 42, in order to adjust the temperature of the device under test 9. The temperature sensing unit 422 may include a thermocouple, a resistance temperature detector (RTD), or other contact or non-contact temperature measurement means.

In some embodiments, the temperature control module 5 is mounted on the circuit board 10. Each temperature control module 5 includes a switch 51, a heater 52, and a cooler 53, where the heater 52 and the cooler 53 are installed in close proximity to or in contact with the device under test 9, such as being located inside the test socket 2 or on the test head (not shown in the figure).

The heater 52 may include a current heating element, a resistive heating source, or other controllable heating equivalent components, and may also include high-temperature fluid piping or chambers. The cooler 53 may consist of thermoelectric modules or a vapor compression refrigeration system (VCRS). In other embodiments, the cooler 53 may also include a fan or be composed of piping or chambers through which low-temperature fluid flows.

The switches 51 are electrically connected to the slave controllers 42, with the heaters 52 and the coolers 53 electrically connected to the switches 51. The master controller 41 or the slave controllers 42 control the switches 51 to activate or deactivate the heaters 52 and the coolers 53 based on the results from the temperature sensing units 422, and therefore the temperature is conditioned. When the heaters 52 are activated, the temperature of the device under test 9 can be increased. When the coolers 53 are increased, the temperature can be lowered. Therefore, the burn-in temperature of the device under test 9 can be automatically maintained. In other embodiments, each switch 51 can also include a power regulation circuit configured to control the output power of the heaters 52 and the coolers 53, thereby realizing more accurate temperature control.

In the embodiment shown in FIG. 2, the master controller 41 includes a storage unit 411, which stores the burn-in temperature setting data 413, and the burn-in temperature setting data 413 contains a burn-in temperature setting of each device under test 9. The master controller 41 compares the sensing results from the temperature sensing units 422 with the burn-in temperature setting data 413, and controls the temperature control modules 5 through the slave controllers 42 to adjust the burn-in temperature of the device under test 9. It is to be specially noted that, in other embodiments, the storage unit 411 can also be arranged on each slave controller 42, meaning that each slave controller 42 can be provided with the storage unit 411. Alternatively, the storage units 411 may be present in either the main controller 41 or the slave controllers 42. In other words, the temperature control condition (the burn-in temperature setting data 413) of each device under test 9 can be stored in either the master controller 41 or the slave controllers 42, or the both.

In other words, in this embodiment, independent temperature control can be applied to each device under test 9 in each test socket 2. For instance, different burn-in temperatures can be set for different devices under test 9, or the same burn-in temperature can be adjusted for the same device under test 9, allowing independent temperature regulation. For example, when some devices under test 9 are operated at high power in an overclocking mode, which generates extremely high temperatures, cooling can be applied to those devices under test 9. On the other hand, if the burn-in temperature dynamic control mechanism is in operation and temperature anomalies persist, the master controller 41 will terminate the burn-in test and immediately stop power supplying from the power source 8, so as to prevent damage to the device under test 9 or the test system.

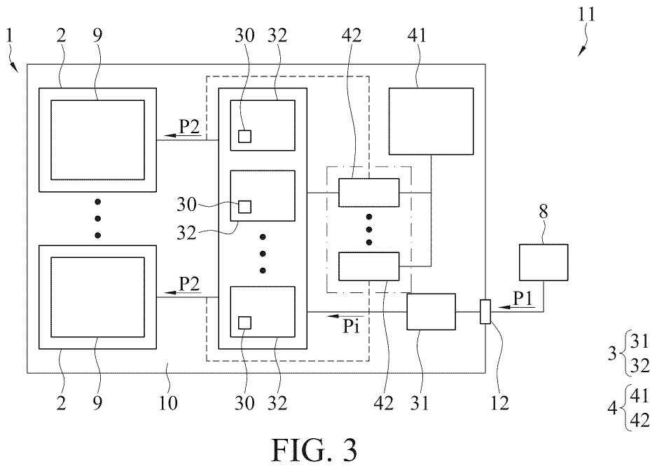

With reference to FIG. 3, it is a system architecture diagram of Embodiment 5 of a dynamic test management burn-in system 11 according to the present disclosure. The primary difference between Embodiment 5 and Embodiment 1 is that the first power P1 in Embodiment 5 undergoes multiple stages of conversion, making it particularly suitable for input power with special specifications (such as ultra-high voltage) or test power with special specifications (such as ultra-high current).

Furthermore, in the embodiment shown in FIG. 3, the power converters 3 include a primary power converter 31 and multiple secondary power converters 32. The primary power converter 31 is electrically connected to the secondary power converters 32 and the power source 8, and the secondary power converters 32 are electrically coupled to the test sockets 2. Specifically, the primary power converter 31 is configured to receive the first power P1 from the power source 8 and perform a first-stage power conversion to generate an intermediate power Pi, which is then respectively supplied to the secondary power converters 32. Moreover, the secondary power converters 32 perform a second-stage power conversion on the intermediate power Pi to generate a second power P2, and the secondary power converters 32 supply the second power P2 to the respective test sockets 2.

Specifically, in some embodiments, the power source 8 provides a high-voltage first power P1 to the primary power converter 31. Since the input power is transmitted in a high-voltage, low-current manner, a power supply interface 12 of the dynamic test management burn-in device 1 can be designed to be relatively simple and compact. In detail, a larger cross-sectional area of a conductor can reduce resistance and heat generation, thereby allowing more current to pass through; thus, transmission lines for high current typically require a larger cross-sectional area. In some embodiments, the cross-sectional area of the power supply interface 12 responsible for transmitting the first power P1 (high voltage and low current) can be smaller than the cross-sectional area of the conductors responsible for transmitting the second power P2 (low voltage and high current). Accordingly, this reduces the number and volume of the power interfaces 12 (e.g., conductors or connectors), enabling sufficient power to be received without requiring numerous interfaces. This can lower manufacturing costs and result in less power loss.

Furthermore, in these embodiments, a two-stage voltage and current conversion is adopted. When the first power P1 is delivered to the dynamic test management burn-in device 1, the primary power converter 31 performs the first-stage processing of stepping down the voltage and increasing the current to generate the intermediate power Pi. Subsequently, the primary power converter 31 distributes the intermediate power Pi to the plurality of secondary power converters 32, which then perform the second-stage processing of stepping down the voltage and increasing the current. Only then do the secondary power converters 32 individually output the second power P2.

In these embodiments, since the current of the first power P1 is lower than the current of the intermediate power Pi, and the current of the intermediate power Pi is lower than the current of the second power P2, the cross-sectional area of the conductors in the power supply interface 12 for the first power P1 can be smaller than the cross-sectional area of the transmission conductors for the intermediate power Pi. Similarly, the cross-sectional area of the transmission conductors for the intermediate power Pi can be smaller than the cross-sectional area of the transmission conductors for the second power P2. Therefore, through the two-stage voltage and current conversion, the power supply interface 12 on the circuit board 10, which is used for electrically connecting to external devices (e.g., the power source 8), can be made simpler and more compact, occupying less volume or space. This is more advantageous for the assembly and maintenance of the circuit board 10.

In addition, even though the second power P2, which carries the highest current, requires thicker transmission conductors, the secondary power converters 32 are positioned adjacent to the test sockets 2, resulting in the shortest transmission path for the second power P2. This helps minimize power loss caused by conductor resistance during high-current transmission. However, in some embodiments, the transmission paths of the second power P2 are shorter than the combined transmission paths of the first power P1 and the intermediate power Pi. In other embodiments, the transmission paths of the power sources may be configured based on current magnitude. For example, the transmission path of the second power P2 may be longer than that of the intermediate power Pi, while the transmission path of the intermediate power Pi may, in turn, be longer than that of the first power P1.

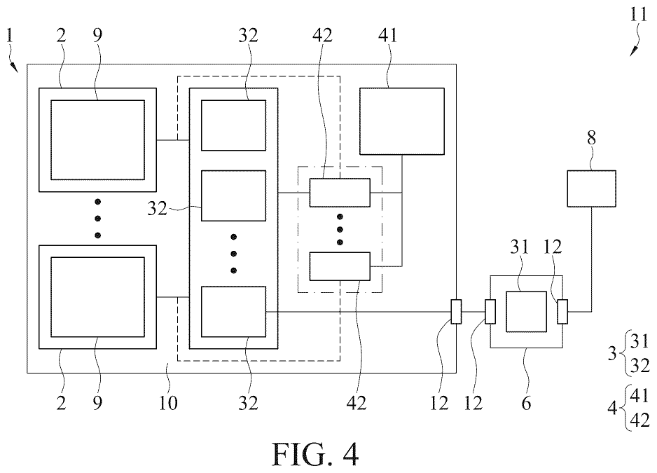

With reference to FIG. 4, it is a system architecture diagram of Embodiment 6 of a dynamic test management burn-in system 11 according to the present disclosure. The main difference between Embodiment 6 and Embodiment 5 is that the dynamic test management burn-in device 1 in Embodiment 6 further includes an adapter board 6. The test sockets 2, the secondary power converters 32, and the controllers 4 are arranged on the circuit board 10. The primary power converter 31 is arranged on the adapter board 6.

Therefore, the inclusion of the adapter board 6 not only enhances the flexibility of all power line configurations but also reduces heat sources on the circuit board 10 by positioning the primary power converter 31 outside the circuit board 10, thereby improving thermal management. In addition, both the circuit board 10 and the adapter board 6 can be equipped with power interfaces 12, such as pluggable connectors, facilitating subsequent assembly and maintenance operations.

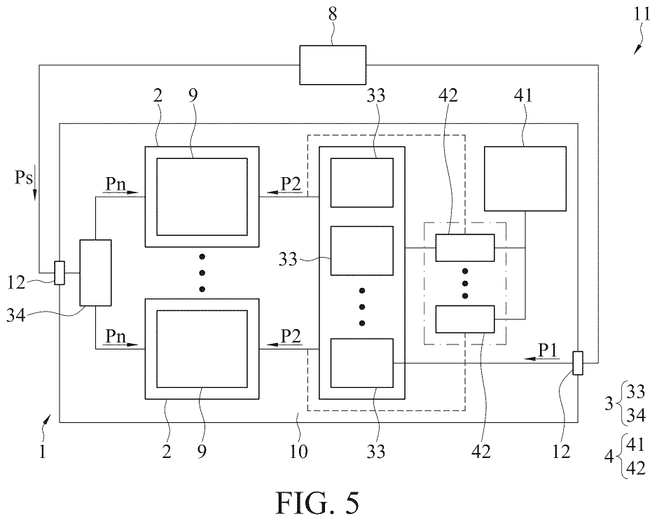

With reference to FIG. 5, it is a system architecture diagram of Embodiment 7 of a dynamic test management burn-in system 11 according to the present disclosure. In Embodiment 7, the power converters 3 include multiple first power converters 33 and at least one second power converter 34, and the power converters 3 are electrically coupled with the test sockets 2 respectively. The first power converters 33 are configured to receive the first power P1 from the power source 8 and to provide the second power P2 for the respective test socket 2. The second power converters 34 are configured to receive an auxiliary power Ps from the power source 8 and to provide a pin power Pn for the respective test sockets 2.

To further elaborate, in some embodiments, the device under test 9 may require power inputs of different specifications. For example, in addition to the primary pins requiring a high-current input for burn-in testing, other secondary pins may only need a low-current power supply. In Embodiment 7, the first power converters 33 can provide the high-current second power P2 for burn-in testing of the primary pins, while the second power converter 34 provides the low-current auxiliary power Ps for the secondary pins. In other words, the power supply for the secondary pins can be managed independently, without affecting the high-current burn-in testing provided by the first power converters 33 to the device under test 9.

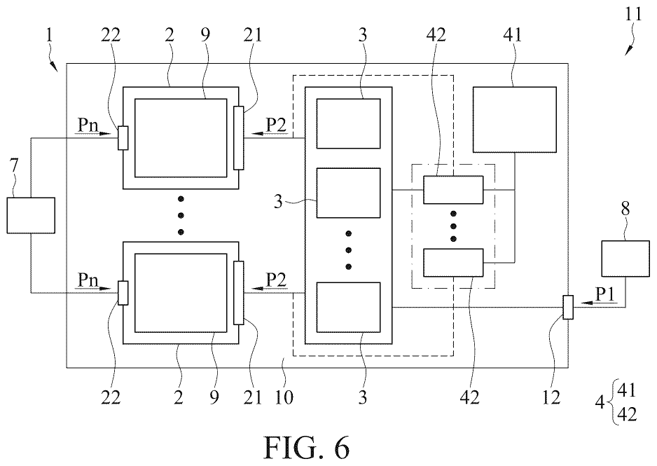

With reference to FIG. 6, it is a system architecture diagram of Embodiment 8 of a dynamic test management burn-in system 11 according to the present disclosure. The main difference between Embodiment 8 and Embodiment 7 is that a secondary pin power Pn in Embodiment 8 is provided by another auxiliary power 7. Specifically, in Embodiment 8, each test socket 2 includes a main power input portion 21 and a secondary power input portion 22. The main power input portion 21 is electrically coupled with the power converters 3 and is configured to receive the second power P2. The secondary power input portion 22 is electrically coupled with the auxiliary power 7 and is configured to receive the pin power Pn.

Overall, according to some embodiments, the input power of the dynamic test management burn-in device 1 adopts a high-voltage and low-current power configuration, significantly reducing the size and number of input power interfaces. For instance, by reducing the number and volume of required power lines, manufacturing costs can be lowered, and power losses can be minimized. Additionally, the use of multiple sets of power converters 3 in parallel to stably supply the test power ensures that the burn-in current required by high-power devices under test 9 is met. Meanwhile, the dynamic test management burn-in device 1 is equipped with power monitoring, protection mechanisms, and burn-in temperature control mechanisms to ensure stable control of both the burn-in power and temperature.

To further elaborate, in some embodiments, the aforementioned dynamic power management technology is provided, which enables monitoring of the power output from the point-of-load (POL) DC power modules. When an abnormality occurs in the output power, the system can automatically compensate and regulate it, quickly restoring it to the preset rated voltage and current. In even more advanced embodiments, the system can also monitor the actual test power supplied by the test sockets 2 to the device under test 9, performing automatic compensation and regulation as well to achieve more precise power management.

Furthermore, in some embodiments, the aforementioned dynamic burn-in temperature control technology can be integrated to provide a stable burn-in temperature for the devices under test 9 throughout the entire burn-in testing process. In more advanced embodiments, independent temperature control can be provided based on the actual operating conditions of each device under test 9, ensuring that every device under test 9 is tested in a precise and stable temperature environment.

Although the present disclosure has been described in considerable detail with reference to certain preferred embodiments thereof, the disclosure is not for limiting the scope of the disclosure. Persons having ordinary skill in the art may make various modifications and changes without departing from the scope and spirit of the disclosure. Therefore, the scope of the appended claims should not be limited to the description of the preferred embodiments described above.

What is claimed is:

1. A dynamic test management burn-in device, comprising:
a plurality of test sockets, each configured to load a device under test;
a plurality of power converters, electrically coupled with the plurality of test sockets, the plurality of power converters being configured to receive a first power from a power source and to provide a second power to the respective test sockets;
a plurality of controllers, electrically coupled with the plurality of power converters; and
a plurality of power detection units, configured to detect at least one of the first power and the second power,
wherein the plurality of controllers control output or activation of the plurality of power converters based on detection results from the plurality of power detection units to supply the second power to the respective test sockets; and a voltage of the first power is higher than that of the second power, while a current of the first power is lower than that of the second power.

2. The dynamic test management burn-in device according to claim 1, wherein the quantity of the plurality of power converters is larger than that of the plurality of test sockets, and the plurality of power converters are interconnected in parallel.

3. The dynamic test management burn-in device according to claim 1, wherein the plurality of controllers comprise a master controller and a plurality of slave controllers; the master controller is electrically connected to the plurality of slave controllers, and the plurality of slave controllers are electrically connected to the plurality of power converters and the plurality of test sockets; and the plurality of power detection units are respectively provided in the plurality of slave controllers.

4. The dynamic test management burn-in device according to claim 3, wherein at least one of the master controller and the plurality of slave controllers comprises a storage unit having power converter configuration data stored therein; the power converter configuration data comprises at least one of the plurality of power converters respectively corresponding to the plurality of test sockets; and the master controller updates the power converter configuration data according to the detection result from the plurality of power detection units.

5. The dynamic test management burn-in device according to claim 3, further comprising a plurality of temperature control modules respectively electrically connected to the plurality of slave controllers, the plurality of slave controllers comprising a plurality of temperature sensing units, wherein the plurality of temperature sensing units are configured to detect a temperature of the respective devices under test in the plurality of test sockets, and the master controller controls the plurality of temperature control modules based on sensing results from the plurality of temperature sensing units through the plurality of slave controllers, so as to condition the temperature of the devices under test.

6. The dynamic test management burn-in device according to claim 5, wherein at least one of the master controller and the slave controllers comprise a storage unit having burn-in temperature setting data stored therein, and the burn-in temperature setting data comprises a burn-in temperature setting for each device under test in each test socket; and wherein the master controller compares the sensing results from the plurality of temperature sensing units with the burn-in temperature setting data, and controls the plurality of temperature control modules through the plurality of slave controllers to condition the burn-in temperature of the device under test.

7. The dynamic test management burn-in device according to claim 6, wherein each temperature control module comprises a switch, a heater, and a cooler; the switch is electrically connected to the plurality of slave controllers; the heater and the cooler are electrically connected to the switch; and the plurality of slave controllers control the switch to activate or deactivate the heater and the cooler, so as to condition the temperature of the device under test and to keep it at the burn-in temperature setting.

8. The dynamic test management burn-in device according to claim 1, wherein the plurality of controllers comprise a master controller and a plurality of slave controllers; the master controller is electrically connected to the plurality of slave controllers; the plurality of slave controllers are electrically connected to the plurality of power converters and the plurality of test sockets; each of the plurality of power detection units is electrically connected to an input end and an output end of each power converter and each test socket; and each of the plurality of power detection units are configured to detect a voltage and current inputted to each of the plurality of power converters, a voltage and current outputted by each of the power converters, and a power supply provided to the device under test in each of the plurality of test sockets, and to respectively transmit a feedback power signal to each of the plurality of slave controllers.

9. The dynamic test management burn-in device according to claim 1, wherein the plurality of power converters comprise at least one primary power converter and a plurality of secondary power converters; the at least one primary power converter is electrically connected to the plurality of secondary power converters, and the plurality of secondary power converters are electrically coupled with the plurality of test sockets; the at least one primary power converter is configured to receive the first power from the power source and to provide an intermediate power to each of the plurality of secondary power converters; and each of the plurality of secondary power converters provide the second power to each of the plurality of test sockets.

10. The dynamic test management burn-in device according to claim 9, further comprising a circuit board and an adapter board, wherein the plurality of test sockets, the plurality of secondary power converters, and the plurality of controllers are arranged on the circuit board, and the at least one primary power converter is arranged on the adapter board.

11. The dynamic test management burn-in device according to claim 1, wherein the plurality of power converters comprise a plurality of first power converters and at least one second power converter, respectively electrically coupled with the plurality of test sockets; the plurality of first power converters are configured to receive the first power from the power source and to provide the second power for each of the plurality of test sockets; and the at least one second power converter is configured to receive an auxiliary power from the power source and to provide a pin power for each of the plurality of test sockets.

12. The dynamic test management burn-in device according to claim 1, wherein each test socket comprises a main power input portion and a secondary power input portion; the main power input portion is electrically coupled with each of the plurality of power converters and is configured to receive the second power; and the secondary power input portion is electrically coupled with an auxiliary power and is configured to receive a pin power.

13. The dynamic test management burn-in device according to claim 1, wherein each power converter comprises a power feedback unit configured to detect a voltage and current inputted to the power converter and a voltage and current outputted by the power converter.

14. A dynamic test management burn-in system, comprising:
a power source, configured to provide a first power;
a plurality of test sockets, each configured to load a device under test;
a plurality of power converters, electrically coupled with the power source and the plurality of test sockets, the plurality of power converters being configured to receive the first power and to provide a second power to the respective test sockets, and the plurality of power converters being configured to reduce a voltage of the first power and boost a current of the first power to generate the second power;
a plurality of controllers, electrically coupled to the plurality of power converters; and
a plurality of power detection units, configured to detect at least one of the first power and the second power,
wherein the plurality of controllers control output or activation of the plurality of power converters based to a detection results from the plurality of power detection units to provide the second power to the respective test sockets.

15. The dynamic test management burn-in system according to claim 14, wherein the quantity of the plurality of power converters is larger than that of the plurality of test sockets, and the plurality of power converters are interconnected in parallel.

16. The dynamic test management burn-in system according to claim 14, wherein the plurality of controllers comprise a master controller and a plurality of slave controllers; the master controller is electrically connected to the plurality of slave controllers, and the plurality of slave controllers are electrically connected to the plurality of power converters and the plurality of test sockets; and the plurality of power detection units are respectively provided in the plurality of slave controllers.

17. The dynamic test management burn-in system according to claim 16, wherein at least one of the master controller and the plurality of slave controllers comprises a storage unit having power converter configuration data stored therein; the power converter configuration data comprises at least one of the plurality of power converters respectively corresponding to the plurality of test sockets; and the master controller updates the power converter configuration data according to the detection result from the plurality of power detection units.

18. The dynamic test management burn-in system according to claim 16, further comprising a plurality of temperature control modules respectively electrically connected to the plurality of slave controllers, the plurality of slave controllers comprising a plurality of temperature sensing units, wherein the plurality of temperature sensing units are configured to detect a temperature of the respective devices under test in the plurality of test sockets, and the master controller controls the plurality of temperature control modules based on sensing results from the plurality of temperature sensing units through the plurality of slave controllers, so as to condition the temperature of the devices under test.

19. The dynamic test management burn-in system according to claim 18, wherein at least one of the master controller and the slave controllers comprise a storage unit having burn-in temperature setting data stored therein, and the burn-in temperature setting data comprises a burn-in temperature setting for each device under test in each test socket; and wherein the master controller compares the sensing results from the plurality of temperature sensing units with the burn-in temperature setting data, and controls the plurality of temperature control modules through the plurality of slave controllers to condition the burn-in temperature of the device under test.

20. The dynamic test management burn-in system according to claim 19, wherein each temperature control module comprises a switch, a heater, and a cooler; the switch is electrically connected to the plurality of slave controllers; the heater and the cooler are electrically connected to the switch; and the plurality of slave controllers control the switch to activate or deactivate the heater and the cooler, so as to condition the temperature of the device under test and to keep it at the burn-in temperature setting.

21. The dynamic test management burn-in system according to claim 14, wherein the plurality of power converters comprise at least one primary power converter and a plurality of secondary power converters; the at least one primary power converter is electrically connected to the plurality of secondary power converters, and the plurality of secondary power converters are electrically coupled with the plurality of test sockets; the at least one primary power converter is configured to receive the first power from the power source and to provide an intermediate power to the plurality of secondary power converters; and the plurality of secondary power converters provide the second power to the respective test sockets.
